(19) United States
(12) Patent Application Publication
(10) Pub. No.: US 2012/0194289 A1
(43) Pub. Date: Aug. 2, 2012

(54) FREQUENCY MODULATION FEEDBACK SYSTEM

(76) Inventor: Yu-Ming Li, (US)

(21) Appl. No.: 13/016,960

(22) Filed: Jan. 28, 2011

(51) Int. Cl. H03C 3/00

(52) U.S. Cl. 332/117

(57) ABSTRACT

A frequency modulation feedback system applied to an actuation device composed of a carrier and a drive unit for driving the carrier. The frequency modulation feedback system includes: a feedback device for reading a feedback signal of the carrier and transmitting the feedback signal; a control section for receiving and reading the feedback signal to drive the drive unit; a passage, the feedback signal being transmitted from the feedback device via the passage to the control section; and a modulation device for modulating the waveform of the transmitted feedback signal. After the feedback device reads the feedback signal, the feedback device first transmits the feedback signal to the modulation device for the modulation device to change the waveform of the feedback signal. Then the feedback signal is transmitted via the passage to the control section for reading.

### BACKGROUND OF THE INVENTION

1. Field of the Invention

The present invention relates generally to a position feedback system, and more particularly to a frequency modulation feedback system.

2. Description of the Related Art

A linear motor is popularly applied to a tool machine. The linear motor via a drive unit drives the tool machine to linearly move along a slide rail. Following the advance of processing technique, it is often necessary to use high-precision measuring equipment for precisely locate the tool machine. In order to precisely linearly move the tool machine to a predetermined position, a position feedback system is often used to sense positional signals of a cooperative magnetic ruler for precisely driving and locating the tool machine.

FIG. 1 shows a conventional position feedback system 1, which includes a sensor 2 and a controller 3. The position feedback system 1 works mainly in the principle that after the sensor 2 senses the signal, the sensor 2 transmits the signal to the controller 3. The controller 3 receives the signal and reads the necessary positional data for successively driving a motor 4. The motor 4 serves to move the tool machine to a predetermined position. In general, the sensor 2 is connected to the controller 3 via a cable for transmitting the signal. In such wired signal transmission, the cable leads to increase of cost. Moreover, the length of the cable will limit the site of use. Also, the cable needs room to be laid out. In the case that the sensor 2 is spaced from the controller 3 by an excessively long distance, the cable will have to have a considerable length. Under such circumstance, the intensity of the signal will inevitably decay with the increase of length or the signal will be interfered with by a noise 5. In this case, the judgment of the controller 3 will be affected.

In order to avoid interference of the noise, another type of conventional position feedback system utilizes A/B phase differential signal to resist against the noise. An anti-noise effect can be achieved by means of amplitude modulation. However, some shortcomings still exist in the conventional system as follows:

1. The quality of the signal is affected due to decay of amplitude.

2. The transmission distance at most is only several tens of meters.

3. The conventional system is more sensitive to interference. Therefore, the conventional system is subject to interference of non-uniform addable voltage noise. In this case, the controller can hardly truly read the signal.

4. The signal can be transmitted simply by means of wired medium.

### SUMMARY OF THE INVENTION

It is therefore a primary object of the present invention to provide a frequency modulation feedback system, which is free from the interference of the voltage noise so that the reliability of the signal is enhanced and the problem of signal decay is overcome.

It is a further object of the present invention to provide the above frequency modulation feedback system, which can transmit the signal wirelessly to elongate signal transmission distance and facilitate use.

It is still a further object of the present invention to provide the above frequency modulation feedback system, which is applicable to both digital signal and analog signal.

To achieve the above and other objects, the frequency modulation feedback system of the present invention is applied to an actuation device composed of a carrier and a drive unit for driving the carrier. The frequency modulation feedback system includes: a feedback device for reading a feedback signal of the carrier and transmitting the feedback signal; a control section for receiving and reading the feedback signal to drive the drive unit; a passage, the feedback signal being transmitted from the feedback device via the passage to the control section; and a modulation device for modulating the waveform of the transmitted feedback signal. After the feedback device reads the feedback signal, the feedback device first transmits the feedback signal to the modulation device for the modulation device to change the waveform of the feedback signal. Then the feedback signal is transmitted via the passage to the control section for reading.

The present invention can be best understood through the following description and accompanying drawings, wherein:

### BRIEF DESCRIPTION OF THE DRAWINGS

FIG. 1 is a block diagram of a conventional position feedback system, showing signal transmission thereof; and

FIG. 2 is a block diagram of a preferred embodiment of the frequency modulation feedback system 10 of the present invention, showing signal transmission thereof.

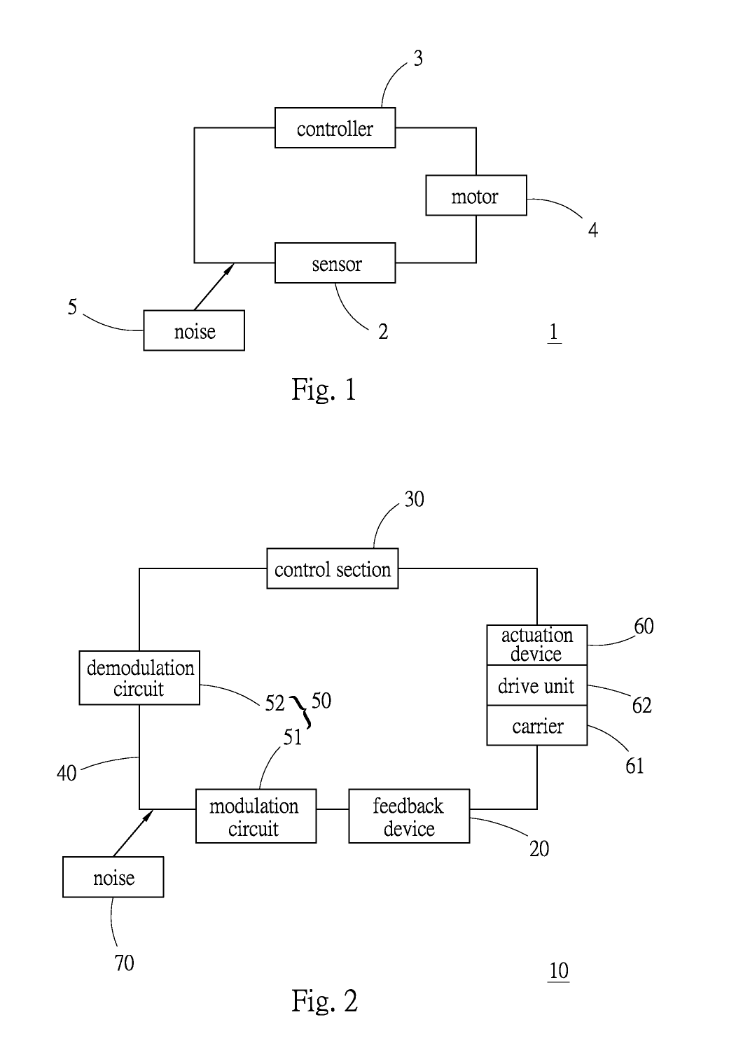

### DETAILED DESCRIPTION OF THE PREFERRED EMBODIMENT

Please refer to FIG. 2. According to a preferred embodiment, the frequency modulation feedback system 10 of the present invention is applied to an actuation device 60. The actuation device 60 includes a carrier 61 slidably mounted on a slide rail and a drive unit 62 formed of a linear motor. The drive unit 62 is installed on the carrier 61 for driving the carrier 61 to linearly move along the slide rail. The actuation device 60 pertains to prior art and is not included in the scope of the present invention. Therefore, the actuation device 60 will not be further described hereinafter.

The frequency modulation feedback system 10 mainly includes a feedback device 20, a control section 30, a passage 40 and a modulation device 50.

The feedback device 20 serves to read a feedback signal of the carrier 61 and transmit the feedback signal.

The control section 30 serves to receive and read the feedback signal to drive the drive unit 62.

The feedback signal is transmitted from the feedback device 20 via the passage 40 to the control section 30.

The modulation device 50 serves to change the waveform of the feedback signal transmitted via the passage 40 by means of frequency modulation. The modulation device 50 includes a modulation circuit 51 for receiving the feedback signal transmitted from the feedback device 20 and modulating the waveform of the feedback signal. The modulation device 50 further includes a demodulation circuit 52 for analyzing the feedback signal with modulated waveform for the control section 30 to read.

According to the above arrangement, when the carrier 61 is driven by the drive unit 62 to linearly move along the slide rail, the feedback device 20 reads the feedback signal of the carrier 61 with the displacement thereof. At the same time, the feedback device 20 transmits the sensed feedback signal. The modulation device 50 is disposed in the passage 40 between the feedback device 20 and the control section 30. Therefore, the feedback signal transmitted from the feedback device 20 is not directly received by the control section 30. Instead, the modulation device 50 will first modulate the waveform of the positional message. To speak more specifically, the modulation circuit 51 serves to modulate the frequency of the feedback signal and change the waveform of the feedback signal into a waveform adapted to the passage 40 to facilitate transmission of the feedback signal. Even if a voltage noise 70 enters the passage during the transmission, the modulated feedback signal will not be interfered with by the noise 70 so that the waveform of the feedback signal will not be affected. Then the demodulation circuit 52 analyzes the modulated positional message for the control section 30 to read. The control section 30 then drives the drive unit 62 to precisely move to a predetermined position or stop at a predetermined position.

In the frequency modulation feedback system 10 of the present invention, the modulation device 50 serves to change the frequency of the feedback signal. In comparison with the original signal, the modulated signal has a higher frequency and shorter wavelength to facilitate signal transmission. This is mainly because that after the frequency of the feedback signal is modulated, the feedback signal will not be interfered with by the voltage noise during the transmission. Also, the signal quality will not be affected due to decay of amplitude. In this case, the signal can be precisely transmitted to the control section 30 for reading. Accordingly, the reliability of the signal is increased.

Moreover, after the feedback signal is modulated, the passage 40 is no more limited to a wired medium. That is, the passage 50 can be also a wireless medium to transmit the feedback signal to the control section 30 wirelessly. Accordingly, a user can elastically select a suitable space or a suitable site for signal transmission as necessary so as to enhance convenience in use. Furthermore, since the signal can be wirelessly transmitted, the transmission distance is not limited by the space. Even if the feedback device 20 is far spaced from the control section 30 by several tens of kilometers, the signal can be still successfully transmitted.

In addition, no matter the signal is a digital one or an analog one, the frequency of the signal can be modulated by means of the present invention.

The above embodiment is only used to illustrate the present invention, not intended to limit the scope thereof. Many modifications of the above embodiment can be made without departing from the spirit of the present invention.

What is claimed is:

1. A frequency modulation feedback system applied to an actuation device, the actuation device being composed of a carrier and a drive unit for driving the carrier, the frequency modulation feedback system comprising:
a feedback device for reading a feedback signal of the carrier and transmitting the feedback signal;
a control section for receiving and reading the feedback signal to drive the drive unit; and
a passage, the feedback signal being transmitted from the feedback device via the passage to the control section, the frequency modulation feedback system being characterized in that the frequency modulation feedback system further comprising a modulation device for modulating the transmitted feedback signal, whereby after the feedback device reads the feedback signal, the feedback device first transmits the feedback signal to the modulation device for the modulation device to modulate the feedback signal, then the feedback signal being transmitted via the passage to the control section for reading.

2. The frequency modulation feedback system as claimed in claim 1, wherein the modulation device includes a modulation circuit for receiving the feedback signal transmitted from the feedback device and modulating the waveform of the feedback signal, the modulation device further including a demodulation circuit for analyzing the feedback signal with modulated waveform for the control section to receive and read.

3. The frequency modulation feedback system as claimed in claim 1, wherein the modulation device serves to change the frequency of the feedback signal.

4. The frequency modulation feedback system as claimed in claim 1, wherein the passage is a wired medium.

5. The frequency modulation feedback system as claimed in claim 1, wherein the passage is a wireless medium.
